(19) United States
(12) Patent Application Publication
(10) Pub. No.: US 2024/0302185 A1
(43) Pub. Date: Sep. 12, 2024

(54) System, Method, and Apparatus for Sensor Drift Compensation

(71) Applicant: CARNEGIE MELLON UNIVERSITY, Pittsburgh, PA (US)

(72) Inventors: Gary K. Fedder, Turtle Creek, PA (US); Tamal Mukherjee, Pittsburgh, PA (US); Vincent P.J. Chung, Pittsburgh, PA (US)

(73) Assignee: Carnegie Mellon University, Pittsburgh, PA (US)

(21) Appl. No.: 18/272,141

(22) PCT Filed: Jan. 14, 2022
(86) PCT No.: PCT/US22/12407

§ 371 Date: Jul. 13, 2023

Related U.S. Application Data
(60) Provisional application No. 63/137,184, filed on Jan. 14, 2021.

(51) Int. Cl. G01D 3/036; B81B 7/02; G01P 15/02; G01P 21/00; G06N 3/08

(52) U.S. Cl. CPC G01D 3/0365; B81B 7/02; G01P 15/02; G01P 21/00; G06N 3/08; B81B 2201/0235; B81B 2201/0242

(57) ABSTRACT

A system includes an inertial sensing device having an inertial sensor and plurality of stress sensors configured to measure stress applied to the inertial sensing device, and at least one computing device configured to: receive sensor data from the inertial sensor and the plurality of stress sensors; and determine a drift compensation of the inertial sensor based on the sensor data. Other systems, methods, and devices are disclosed.

### CROSS REFERENCE TO RELATED APPLICATION

This application claims priority to U.S. Provisional Patent Application No. 63/137,184, filed Jan. 14, 2021, the disclosure of which is hereby incorporated by reference in its entirety.

### BACKGROUND

### 1. Field

The technology of the disclosure relates generally to sensors and, in non-limiting embodiments, to systems, methods, and apparatuses for compensating for drift in an inertial sensor.

### 2. Technical Considerations

Acceleration random walk is widely modeled as an error from random processes. The advancement in micro-electromechanical system (MEMS) technology has made possible portable and strap-down inertial navigation systems. Identifying and modeling the error sources that degrade the performance of MEMS-based inertial sensors is important to enable accurate tracking in navigation systems. Examples of error sources in MEMS-based inertial navigation systems include sensor offset, white noise, pink or flicker noise, and Brownian noise as described in the frequency domain. For accelerometers, these three noise error sources correspond to velocity random walk, bias instability, and accelerometer random walk, respectively, as described in the time domain, for example in Allan variance analysis. For gyroscopes, the three noise error sources correspond to angle random walk, bias instability, and rate random walk, respectively. The error sources can be further categorized into stochastic errors and deterministic errors. Acceleration and rate random walk, the key indicators of the long-term performance of accelerometers and gyroscopes, respectively, are modeled as stochastic errors in existing systems. Due to their low-frequency nature, acceleration and rate random walk are often referred to as aging that is typically specified as “long-term stability” or “drift over lifetime” in product data sheets and literature. Bias instability in an Allan variance analysis is a measure of the lowest noise achievable from the sensor data. Many emerging navigation applications require inertial sensors featuring very low bias instability. However, acceleration and rate random walk may be at levels that overwhelm the sensor flicker noise that sets the bias instability limit and drives a need for compensating for acceleration and rate random walk.

Temperature is correlated to acceleration and rate random walk of inertial navigation systems. Therefore, temperature-induced drift compensation or oven-stabilized packaging is implemented in some accelerometers and gyroscopes to attain lower bias drift over time. MEMS-based inertial sensors are also known to be susceptible to stress conditions, such as packaging induced stress. For this reason, many commercial MEMS-based inertial sensors provide strict guidelines for mounting and soldering the parts, and cannot be flexibly utilized outside of these guideline without being adversely affected. Moreover, the use of a single stress sensor to provide stress-and-temperature-induced drift compensation does not completely null the rate random walk when the inertial sensing device encounters external stresses because a single stress sensor is unable to capture stress states across the device.

### SUMMARY

According to non-limiting embodiments or aspects, provided is a system comprising: an inertial sensing device comprising: an inertial sensor; and a plurality of stress sensors configured to measure stress applied to the inertial sensing device; and at least one computing device configured to: receive sensor data from the inertial sensor and the plurality of stress sensors; and determine a drift compensation of the inertial sensor based on the sensor data.

In non-limiting embodiments or aspects, the inertial sensing device comprises the at least one computing device. In non-limiting embodiments or aspects, the at least one computing device comprises at least one first processor arranged in the sensing device and at least one second processor external to the sensing device. In non-limiting embodiments or aspects, the inertial sensing device further comprises a plurality of environmental sensors in addition to the plurality of stress sensors, and the drift compensation is determined at least partially based on sensor data received from the plurality of environmental sensors. In non-limiting embodiments or aspects, the plurality of environmental sensors comprises at least one of the following: a temperature sensor, a resonator oscillator sensor, a strain sensor, a gas chemical sensor, or any combination thereof.

In non-limiting embodiments or aspects, the sensor data is received while the inertial sensing device is moved. In non-limiting embodiments or aspects, the at least one computing device is further configured to record the sensor data to temporally associate measurements from the inertial sensor with stress measurements from the plurality of stress sensors. In non-limiting embodiments or aspects, determining the drift compensation is based on a machine-learning algorithm. In non-limiting embodiments or aspects, the machine-learning algorithm comprises a deep neural network. In non-limiting embodiments or aspects, the deep neural network comprises a first fully-connected hidden layer, a second fully-connected hidden layer, and a third fully-connected hidden layer. In non-limiting embodiments or aspects, the machine-learning algorithm outputs a predicted drift value, and the drift compensation is based on the predicted drift value.

In non-limiting embodiments or aspects, the inertial sensor comprises an array of accelerometers. In non-limiting embodiments or aspects, the inertial sensor comprises at least one gyroscope or an array of gyroscopes. In non-limiting embodiments or aspects, the inertial sensing device comprises a chip, and the inertial sensor and the plurality of stress sensors are arranged on the chip. In non-limiting embodiments or aspects, the system further comprises a data storage device comprising an association between each stress sensor of the plurality of stress sensors and at least one of the following: an accelerometer of the array of accelerometers, a position on the chip supporting the array of accelerometers, a position on the chip relative to an accelerometer of the array of accelerometers, or any combination thereof. In non-limiting embodiments or aspects, the system further comprises a testbed computing device in communication with the inertial sensing device, the testbed computing device configured to generate signals configured to produce the sensor data from the inertial sensor and the plurality of stress sensors.

According to non-limiting embodiments or aspects, provided is a method comprising: capturing a plurality of inertial sensor signals comprising inertial sensor data from at least one inertial sensor arranged in an inertial sensing device while the inertial sensing device is moved; capturing a plurality of environmental sensor signals comprising environmental sensor data from a plurality of stress sensors arranged in the inertial sensing device while the inertial sensing device is moved; temporally associating the inertial sensor data with the environmental sensor data; and determining, with at least one processor, a drift compensation for the at least one inertial sensor based on the inertial sensor data and the environmental sensor data.

In non-limiting embodiments or aspects, the method further comprises: adjusting a configuration of the at least one inertial sensor based on the drift compensation. In non-limiting embodiments or aspects, adjusting the configuration of the at least one inertial sensor comprises at least one of the following: modifying an attribute of the at least one inertial sensor, modifying an algorithm that processes the inertial sensor data, or any combination thereof. In non-limiting embodiments or aspects, determining the drift compensation comprises: inputting the environmental sensor data into a machine-learning model configured to output a predicted drift value, the drift compensation is based on the predicted drift value. In non-limiting embodiments or aspects, the machine-learning model comprises a deep neural network comprising a first fully-connected hidden layer, a second fully-connected hidden layer, and a third fully-connected hidden layer. In non-limiting embodiments or aspects, the method further comprises training the machine-learning model based on training input data generated with a testbed computing device.

According to non-limiting embodiments or aspects, provided is an inertial sensing device comprising: an inertial sensor; and a plurality of stress sensors arranged on the inertial sensing device and configured to measure stress applied to the inertial sensing device.

In non-limiting embodiments or aspects, the inertial sensing device further comprises an interface configured to output sensor data from the inertial sensor and the plurality of stress sensors. In non-limiting embodiments or aspects, the inertial sensing device further comprises a plurality of temperature sensors. In non-limiting embodiments or aspects, the inertial sensing device further comprises at least one computing device configured to determine a drift compensation of the inertial sensor based on sensor data from the inertial sensor and the plurality of stress sensors.

In non-limiting embodiments or aspects, the drift compensation is determined based on a machine-learning model. In non-limiting embodiments or aspects, the machine-learning model comprises a deep neural network. In non-limiting embodiments or aspects, the deep neural network comprises a first fully-connected hidden layer, a second fully-connected hidden layer, and a third fully-connected hidden layer. In non-limiting embodiments or aspects, the machine-learning model outputs a predicted drift value, and the drift compensation is based on the predicted drift value. In non-limiting embodiments or aspects, the inertial sensor comprises an array of accelerometers. In non-limiting embodiments or aspects, the inertial sensor comprises at least one gyroscope or an array of gyroscopes. In non-limiting embodiments or aspects, the inertial sensing device further comprises a chip, the chip including the inertial sensor and the plurality of stress sensors.

According to non-limiting embodiments or aspects, provided is a system comprising: a sensing device comprising: at least one micromechanical sensor; and a plurality of environmental sensors configured to measure at least one environmental parameter of the sensing device; and at least one computing device configured to: receive sensor data from the at least one micromechanical sensor and the plurality of environmental sensors; and determine a drift compensation of the micromechanical sensor based on the sensor data.

In non-limiting embodiments or aspects, the plurality of environmental sensors comprises at least one of the following types of sensors: a stress sensor, a temperature sensor, a resonance oscillator sensor, a strain sensor, a gas chemical sensor, or any combination thereof. In non-limiting embodiments or aspects, the at least one micromechanical sensor comprises at least one of the following: an inertial sensor, a resonant gravimetric sensor, a resonant timing device, or any combination thereof.

Other non-limiting embodiments or aspects will be set forth in the following numbered clauses:

Clause 1: A system comprising: an inertial sensing device comprising: an inertial sensor; and a plurality of stress sensors configured to measure stress applied to the inertial sensing device; and at least one computing device configured to: receive sensor data from the inertial sensor and the plurality of stress sensors; and determine a drift compensation of the inertial sensor based on the sensor data.

Clause 2: The system of clause 1, wherein the inertial sensing device comprises the at least one computing device.

Clause 3: The system of clauses 1 or 2, wherein the at least one computing device comprises at least one first processor arranged in the sensing device and at least one second processor external to the sensing device.

Clause 4: The system of any of clauses 1-3, wherein the inertial sensing device further comprises a plurality of environmental sensors in addition to the plurality of stress sensors, and wherein the drift compensation is determined at least partially based on sensor data received from the plurality of environmental sensors.

Clause 5: The system of any of clauses 1-4, wherein the plurality of environmental sensors comprises at least one of the following: a temperature sensor, a resonator oscillator sensor, a strain sensor, a gas chemical sensor, or any combination thereof.

Clause 6: The system of any of clauses 1-5, wherein the sensor data is received while the inertial sensing device is moved.

Clause 7: The system of any of clauses 1-6, wherein the at least one computing device is further configured to record the sensor data to temporally associate measurements from the inertial sensor with stress measurements from the plurality of stress sensors.

Clause 8: The system of any of clauses 1-7, wherein determining the drift compensation is based on a machine-learning algorithm.

Clause 9: The system of any of clauses 1-8, where the machine-learning algorithm comprises a deep neural network.

Clause 10: The system of any of clauses 1-9, wherein the deep neural network comprises a first fully-connected hidden layer, a second fully-connected hidden layer, and a third fully-connected hidden layer.

Clause 11: The system of any of clauses 1-10, wherein the machine-learning algorithm outputs a predicted drift value, and wherein the drift compensation is based on the predicted drift value.

Clause 12: The system of any of clauses 1-11, wherein the inertial sensor comprises an array of accelerometers.

Clause 13: The system of any of clauses 1-12, wherein the inertial sensor comprises at least one gyroscope or an array of gyroscopes.

Clause 14: The system of any of clauses 1-13, wherein the inertial sensing device comprises a chip, and wherein the inertial sensor and the plurality of stress sensors are arranged on the chip.

Clause 15: The system of any of clauses 1-14, further comprising a data storage device comprising an association between each stress sensor of the plurality of stress sensors and at least one of the following: an accelerometer of the array of accelerometers, a position on the chip supporting the array of accelerometers, a position on the chip relative to an accelerometer of the array of accelerometers, or any combination thereof.

Clause 16: The system of any of clauses 1-15, further comprising: a testbed computing device in communication with the inertial sensing device, the testbed computing device configured to generate signals configured to produce the sensor data from the inertial sensor and the plurality of stress sensors.

Clause 17: A method comprising: capturing a plurality of inertial sensor signals comprising inertial sensor data from at least one inertial sensor arranged in an inertial sensing device while the inertial sensing device is moved; capturing a plurality of environmental sensor signals comprising environmental sensor data from a plurality of stress sensors arranged in the inertial sensing device while the inertial sensing device is moved; temporally associating the inertial sensor data with the environmental sensor data; and determining, with at least one processor, a drift compensation for the at least one inertial sensor based on the inertial sensor data and the environmental sensor data.

Clause 18: The method of clause 17, further comprising: adjusting a configuration of the at least one inertial sensor based on the drift compensation.

Clause 19: The method of clauses 17 or 18, wherein adjusting the configuration of the at least one inertial sensor comprises at least one of the following: modifying an attribute of the at least one inertial sensor, modifying an algorithm that processes the inertial sensor data, or any combination thereof.

Clause 20: The method of any of clauses 17-19, wherein determining the drift compensation comprises: inputting the environmental sensor data into a machine-learning model configured to output a predicted drift value, wherein the drift compensation is based on the predicted drift value.

Clause 21: The method of any of clauses 17-20, wherein the machine-learning model comprises a deep neural network comprising a first fully-connected hidden layer, a second fully-connected hidden layer, and a third fully-connected hidden layer.

Clause 22: The method of any of clauses 17-21, wherein the at least one computing device is further configured to: train the machine-learning model based on training input data generated with a testbed computing device.

Clause 23: An inertial sensing device comprising: an inertial sensor; and a plurality of stress sensors arranged on the inertial sensing device and configured to measure stress applied to the inertial sensing device.

Clause 24: The inertial sensing device of clause 23, further comprising an interface configured to output sensor data from the inertial sensor and the plurality of stress sensors.

Clause 25: The inertial sensing device of clauses 23 or 24, further comprising a plurality of temperature sensors.

Clause 26: The inertial sensing device of any of clauses 23-25, further comprising at least one computing device configured to determine a drift compensation of the inertial sensor based on sensor data from the inertial sensor and the plurality of stress sensors.

Clause 27: The inertial sensing device of any of clauses 23-26, wherein the drift compensation is determined based on a machine-learning model.

Clause 28: The inertial sensing device of any of clauses 23-27, wherein the machine-learning model comprises a deep neural network.

Clause 29: The inertial sensing device of any of clauses 23-28, wherein the deep neural network comprises a first fully-connected hidden layer, a second fully-connected hidden layer, and a third fully-connected hidden layer.

Clause 30: The inertial sensing device of any of clauses 23-29, wherein the machine-learning model outputs a predicted drift value, and wherein the drift compensation is based on the predicted drift value.

Clause 31: The inertial sensing device of any of clauses 23-30, wherein the inertial sensor comprises an array of accelerometers.

Clause 32: The inertial sensing device of any of clauses 23-31, wherein the inertial sensor comprises at least one gyroscope or an array of gyroscopes.

Clause 33: The inertial sensing device of any of clauses 23-32, further comprising a chip, the chip including the inertial sensor and the plurality of stress sensors.

Clause 34: A system comprising: a sensing device comprising: at least one micromechanical sensor; and a plurality of environmental sensors configured to measure at least one environmental parameter of the sensing device; and at least one computing device configured to: receive sensor data from the at least one micromechanical sensor and the plurality of environmental sensors; and determine a drift compensation of the micromechanical sensor based on the sensor data.

Clause 35: The system of clause 34, wherein the plurality of environmental sensors comprises at least one of the following types of sensors: a stress sensor, a temperature sensor, a resonance oscillator sensor, a strain sensor, a gas chemical sensor, or any combination thereof.

Clause 36: The system of clauses 34 or 35, wherein the at least one micromechanical sensor comprises at least one of the following: an inertial sensor, a resonant gravimetric sensor, a resonant timing device, or any combination thereof.

Clause 37: The system of clause 1, wherein the inertial sensor comprises an array of gyroscopes.

Clause 38: The system of clause 1, wherein the inertial sensor comprises a plurality of accelerometers and a plurality of gyroscopes.

Clause 39: The system of clause 34, wherein the plurality of environmental sensors comprise a plurality of magnetometers.

These and other features and characteristics of the present disclosure, as well as the methods of operation and functions of the related elements of structures and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention.

### BRIEF DESCRIPTION OF THE DRAWINGS

Additional advantages and details are explained in greater detail below with reference to the non-limiting, exemplary embodiments that are illustrated in the accompanying figures, in which:

FIG. 1A illustrates a system for compensating for drift of an inertial sensor according to non-limiting embodiments or aspects;

FIG. 1B illustrates an inertial sensor according to non-limiting embodiments or aspects;

FIG. 2 illustrates a system for compensating for drift of an inertial sensor according to non-limiting embodiments or aspects;

FIG. 3 illustrates a portion of an accelerometer array with stress sensors according to non-limiting embodiments or aspects of a system for compensating for drift of an inertial sensor;

FIG. 4 illustrates a neural network architecture according to non-limiting embodiments or aspects of a system for compensating for drift of an inertial sensor;

FIG. 5 illustrates a flow diagram for a method of compensating for drift of an inertial sensor according to non-limiting embodiments or aspects; and

FIG. 6 illustrates an Allan deviation analysis for a bias drift of an accelerometer.

### DETAILED DESCRIPTION

It is to be understood that the embodiments may assume various alternative variations and step sequences, except where expressly specified to the contrary. It is also to be understood that the specific devices and processes described in the following specification are simply exemplary embodiments or aspects of the disclosure. Hence, specific dimensions and other physical characteristics related to the embodiments or aspects disclosed herein are not to be considered as limiting. No aspect, component, element, structure, act, step, function, instruction, and/or the like used herein should be construed as critical or essential unless explicitly described as such. Also, as used herein, the articles “a” and “an” are intended to include one or more items and may be used interchangeably with “one or more” and “at least one.” Also, as used herein, the terms “has,” “have,” “having,” or the like are intended to be open-ended terms. Further, the phrase “based on” is intended to mean “based at least partially on” unless explicitly stated otherwise.

As used herein, the term “computing device” may refer to one or more electronic devices configured to process data. A computing device may, in some examples, include the necessary components to receive, process, and output data, such as a processor, a display, a memory, an input device, a network interface, and/or the like. A computing device may be a mobile device. A computing device may also be a desktop computer or other form of non-mobile computer. In non-limiting embodiments, a computing device may include a GPU, a CPU, a processor, a microprocessor, a controller, a microcontroller, and/or the like. In non-limiting embodiments, a computing device may be comprised of a plurality of circuits.

As used herein, the term “communication” may refer to the reception, receipt, transmission, transfer, provision, and/or the like, of data (e.g., information, signals, messages, instructions, commands, and/or the like). For one unit (e.g., a device, a system, a component of a device or system, combinations thereof, and/or the like) to be in communication with another unit means that the one unit is able to directly or indirectly receive information from and/or transmit information to the other unit. This may refer to a direct or indirect connection (e.g., a direct communication connection, an indirect communication connection, and/or the like) that is wired and/or wireless in nature. Additionally, two units may be in communication with each other even though the information transmitted may be modified, processed, relayed, and/or routed between the first and second unit. For example, a first unit may be in communication with a second unit even though the first unit passively receives information and does not actively transmit information to the second unit. As another example, a first unit may be in communication with a second unit if at least one intermediary unit processes information received from the first unit and communicates the processed information to the second unit.

Non-limiting embodiments provide for an improved inertial sensing device that compensates for acceleration and rate random walk bias drift (hereinafter referred to as “drift”) during use over a period of time (e.g., several hours). These advantages are realized in part by modeling acceleration random walk as a deterministic error (e.g., based on temperature and stress states), rather than modeling this metric as an error from random processes. For example, a unique arrangement of environmental sensors with respect to one or more inertial sensors (e.g., accelerometers and/or gyroscopes) allows for sensor data to be sequentially collected and processed to determine a predicted drift compensation for the one or more inertial sensors, thereby improving the performance and accuracy of the inertial sensor through long-term use by allowing for compensation during operation of an inertial sensing or navigation system, or other application-based system that includes the inertial sensor. In some non-limiting embodiments, such a unique arrangement of environmental sensors may additionally or alternatively be used with respect to one or more other micromechanical sensors that experience drift (e.g., such as a resonant gravimetric sensor or a resonant timing device). Moreover, the use of machine-learning techniques incorporating a deep neural network allows for the drift compensation to be accurately modeled based on functions learned from training data. Non-limiting embodiments described herein improve the performance of an inertial sensing device by suppressing predicted long-term variations of inertial sensor output corresponding to the drift, thereby compensating for this eventual drift over a period of time of usage. Moreover, inertial navigation systems or other application-based systems incorporating an improved inertial sensing device as described herein benefit from enhanced performance as a result of the improved, compensated inertial sensor outputs.

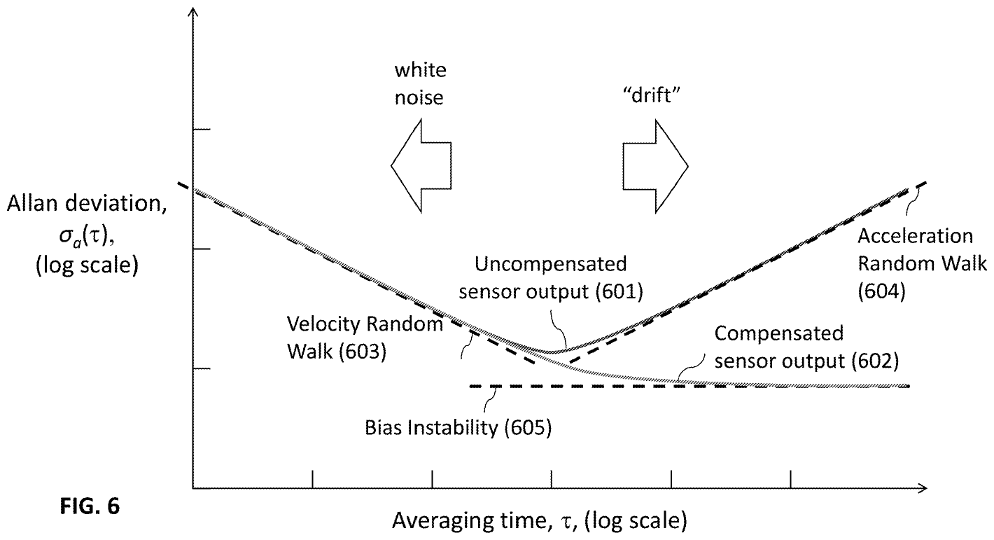

With reference to FIG. 6, shown is a chart of a simplified Allan deviation analysis for an accelerometer. The chart of FIG. 6 shows an uncompensated sensor output 601 over time in relation to velocity random walk 603 and acceleration random walk 604. The chart of FIG. 6 illustrates an ideal drift compensation as compensated sensor output 602 that eliminates all acceleration random walk and results in a low bias instability 605. Non-limiting embodiments of the systems, methods, and apparatuses described herein seek to generate a compensated sensor output that eliminates at least a portion of the drift (e.g., lowers the amount of drift toward the ideal compensated sensor output 602 with respect to the bias drift (acceleration random walk 603)). Although the chart in FIG. 6 shows the Allan deviation analysis for an accelerometer, it will be appreciated that similar analyses and resulting bias instabilities may result from compensating the drift from other types of sensors.

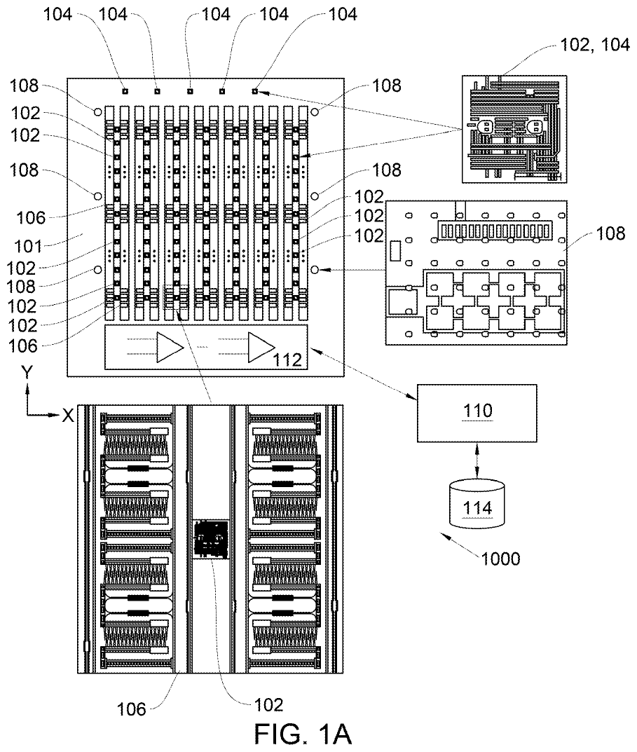

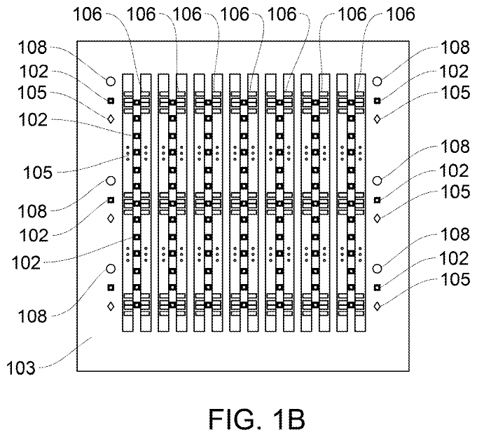

Referring now to FIG. 1A, a system 1000 for compensating for drift of an inertial sensing device 101 is shown according to non-limiting embodiments or aspects. The system 1000 includes an inertial sensing device 101 and a computing device 110. The inertial sensing device 101 may be a chip that includes one or more inertial sensors 106 and a plurality of environmental sensors 102, 104, 108.

The computing device 110 may be arranged on and/or internal to the inertial sensing device 101 in some embodiments. For example, the computing device 110 may be a processor arranged on a chip (e.g., a microfabricated chip of silicon or other substrate material) or printed circuit board (PCB) with other components of an inertial sensing device 101 and/or in a housing that also includes the inertial sensing device 101, such as a controller, microcontroller, microprocessor, and/or the like. Alternatively, the computing device 110 may be external to and/or remote from the inertial sensing device 101, such as a computing device in local communication (e.g., over a wired, Bluetooth®, local network, or other like connection) with the inertial sensing device 101 or a computing device in remote communication (e.g., over an Internet, cellular, remote server, or other like connection). It will be appreciated that in some non-limiting embodiments the computing device 110 may include more than one computing device, such that some processing tasks are performed by a computing device local to the inertial sensing device 101 and other processing tasks are performed by a computing device remote from the inertial sensing device.

In non-limiting embodiments, inertial sensing device 101 may be in the form of a complementary metal-oxide semiconductor (CMOS) micro-electromechanical system (MEMS) device (e.g., a CMOS-MEMS chip). The inertial sensing device 101 may include a device packaging and/or housing. The inertial sensing device 101 may include an interface 112 (e.g., a transduction and communications interface), such as an interface application-specific integrated circuit (ASIC), for enabling sensor data to be converted into electrical form (e.g., a sensor signal) and be amplified, and to be communicated to and received by an external device (e.g., computing system 110).

The inertial sensing device 101 may include one or more inertial sensors 106 (e.g., one or more accelerometers, gyroscopes, and/or the like). As shown in FIG. 1A, the inertial sensor 106 may include an array of accelerometers (e.g., accelerometer cells) arranged on a chip. The inertial sensing device 101 also includes a plurality of environmental sensors 102, 104, 108 arranged on the chip, such as stress sensors 102, 104 and temperature sensors 108. In non-limiting embodiments, environmental sensors arranged on the chip may include one or more of stress sensors, temperature sensors, resonator oscillator sensors, capacitive strain sensors, gas chemical sensors, and/or any other sensor configured to measure an environmental parameter experienced by the chip (e.g., environmental effects on the sensor die). In the depicted non-limiting example of FIG. 1A, the stress sensors include a plurality of y-axis stress sensors 102 and a plurality of x-axis stress sensors 104 configured to respectively measure stress in different dimensions. Each of the sensors 102, 104, 106, 108 output sensor signals representative of measurements output by each sensor (e.g., a voltage or other like output). As used herein, the term “sensor data” may refer to sensor signals and/or information derived from such sensor signals.

The non-limiting example shown in FIG. 1A includes 91 y-axis stress sensors integrated with a 184-element accelerometer array at the anchor region, 5 x-axis stress sensors at the north of the main accelerometer array, and 6 temperature sensors at the east and west side of the main accelerometer array. This results in a total of 102 environmental sensors. It will be appreciated that various other arrangements are possible, and that the number and arrangement of environmental sensors 102, 104, 108 and inertial sensors 106 shown in FIG. 1A is for example purposes only.

In non-limiting embodiments, the inertial sensing device may include resonator oscillators and/or resonant frequency sensors (not shown in FIG. 1A or 1B) to serve as scale factor sensors, where the geometries of the oscillators match the accelerometer design. For example, several (e.g., between 6 and 12 in some examples) resonator oscillators may be arranged on the accelerometer array based on how the accelerometer cells are arranged. In non-limiting embodiments, the resonator oscillator design may mimic the design of the micromechanical transducer forming the inertial sensor, making its resonant angular frequency (e.g. ωᵣ=√(k/m), where m is transducer mass and k is transducer spring constant), be related directly to the inertial sensor scale factor (e.g . . . dx/da=m/k, where x is the measured displacement and a is acceleration). In some examples, sidewalls of the resonators are coated (e.g., in platinum or titanium) to provide increased frequency stability to act as a scale-factor sensor. In non-limiting embodiments, the inertial sensing device may include other environmental sensors beyond stress sensors and resonator oscillators, for example, capacitive strain sensors and gas chemical sensors.

The stress sensors 102, 104 may include piezo-field effect transistor (FET) sensors, piezo-resistive sensors, and/or any suitable sensor for measuring stress in one or more dimensions. Piezo-FETs are transistor-based stress sensors. In non-limiting examples, the stress sensors 102, 104 may each include four FETs in a Wheatstone bridge configuration. For a given sensor area piezo-FETs have slightly lower sensitivity of stress resolution (e.g., a shear piezo-resistive coefficient of 1110 TPa⁻¹) compared to low-doped silicon (e.g., 1381 TPa⁻¹), but experience lower noise compared to diffused-silicon sensors. Non-limiting embodiments utilizing piezo-FET sensors provide the same approximate level of on-chip stress resolution (e.g., 4 kPa) and requires approximately one-tenth of the sensor footprint as compared with other arrangements such as a Wheatstone bridge configuration of piezo-resistors as a piezo-resistive sensor.

The temperature sensors 108 may include proportional-to-absolute temperature (PTAT) sensors and/or any suitable sensor for measuring a temperature of at least a portion of the inertial sensing device 101. In non-limiting embodiments, the inertial sensing device 101 may include stress sensors 102, 104 but not temperature sensors 108, and may therefore operate without any temperature measurements. Combining on-chip temperature measurements with stress measurements, however, will likely provide enhanced accuracy when determining a drift compensation.

Stress and strain effects on the chip (e.g., directly on the inertial sensing device 101), either from externally applied stress or from temperature-based expansion of materials, alters the anchor points of the inertial sensors 106 (e.g., accelerometer transducers), which in turn affects the scale factor. Likewise, gradients in stress may affect the bias because gradients may create unequal displacement between the two sensor capacitors on a transducer cell. In non-limiting embodiments, a threshold of error correction may be pursued during configuration and/or manufacturing of an inertial sensing device. For example, non-limiting embodiments are configured to achieve a scale factor error for the inertial sensor of approximately 1 ppm and to eliminate bias drift up to 1,000 seconds.

In non-limiting embodiments, the arrangement of the inertial sensors 106 may be affected by stress and strain, such that the distance between anchor points of the stator and rotor on an accelerometer transducer may expand (e.g., a distance of 47.5 μm may be expanded by 0.375 nm for a 5 MPa applied stress). Other designs may use, for example, a larger distance between anchor points of the rotor and stator (e.g., 87 μm) which results in a higher corresponding displacement sensitivity (e.g., 137 pm/MPa). In some designs, sense capacitors may be a hybrid comb-finger/parallel-plate design that reduces the sensitivity effect on the scale factor. In some non-limiting embodiments, a lateral etch of the silicon substrate underneath the CMOS-MEMS inertial sensors creating an overhang of CMOS dielectric connected to the transducer anchors (e.g., 30 μm etch creating a 30 μm-wide overhang). In this example, the stress propagates from the substrate into the overhang and causes an attenuation factor (e.g., approximately 0.26) of the displacement at the anchor points compared to the displacement in the bulk substrate. The width of the overhang, and thus the amount of lateral undercut, will change the stress at the anchor points. The three-dimensional nature of the etch trench may also affect the stress propagation.

In non-limiting embodiments, the thermally-induced stress may be quantified through testing and/or simulation, where it can be found that a 100° C. temperature increase results in silicon substrate expansion according to a temperature coefficient of expansion of 2.6×10⁻⁶/° C., causing a 30 nm displacement across a 114 μm-wide slice. The CMOS dielectric overhang attenuates the stress propagated from the substrate. In some examples, the displacement difference between rotor to stator anchors, nominally spaced at a distance of 47.5 μm, is 3 nm. This kind of displacement can also be a result of some accelerometer designs in which the bending of the stator and rotor capacitor electrodes arises from an asymmetric layout of embedded metal wiring where the electrode side of the truss has CMOS layers m1,2,3 of metal wiring while the outer side of the truss is absent the metal. This design creates a temperature-dependent bending moment in the electrode truss that widens the gap as temperature changes. Other non-limiting embodiments improve upon this by adding symmetric metal wiring in the electrode truss. The capacitive gaps then widen by a uniform amount dictated by the anchor expansion rate of 30 pm/° C.

FIG. 1B illustrates an inertial sensing device 103 with an alternative sensor layout according to non-limiting embodiments. In the example shown in FIG. 1B, shear piezo-resistive sensors 105 are used in place of several (e.g., half) y-stress piezo-FET sensors 102. It will be appreciated that, in the examples described herein with respect to FIG. 1B, that sensors 105 may be used in place of and/or in addition to one or more of environmental sensors 102, 104.

In non-limiting embodiments, the outputs (e.g., sensor signals) of the sensors 102, 104, 106, 108 are processed by the computing device 110 to determine a drift compensation based on a predicted drift value, which may include a bias prediction and a scale factor error prediction. For example, the computing device 110 may be configured to determine a value to compensate for the drift (e.g., acceleration random walk) experienced by the inertial sensors 106. The sensor signals output by environmental sensors 102, 104, 108 and inertial sensors 106 may be monitored and the sensor data stored during real-time operation. In some examples, the sensor signals and/or sensor data may be stored in temporal relation such that each time period or time instance is associated with one or more sensor signals and/or sensor data from each of the sensors 102, 104, 108 and inertial sensors 106. The sensor signals and/or sensor data may be stored in temporal sequence as output during operation. In some non-limiting embodiments, the sensor signals and/or sensor data may be stored in a data storage device 114 in communication with the computing device 110. The sensor signals and/or sensor data may be captured and stored in real-time during operation (e.g., at the same time or substantially the same time as the measurements are obtained).

In some non-limiting embodiments, the data storage device 114 or another data storage device may include configuration information for the inertial sensing device 101. Configuration information may include, for example, associations between sensors 102, 104, 108, 106, and/or other data, such as location data for each sensor (e.g., a location of environmental sensor 102 on a chip or PCB, either as an absolute location or a relative location with respect to an inertial sensor 106). In some examples, the configuration information may include associations between each inertial sensor 106 and one or more corresponding environmental sensors adjacent and/or proximate the inertial sensor 106. The environmental sensors 102, 104, 108 and inertial sensor 106 may be associated with unique identifiers for storing associations and other configuration information.

Although the example shown in FIG. 1A depicts accelerometers as the inertial sensors 106, non-limiting embodiments or aspects may additionally or alternatively utilize one or more gyroscopes that measure angular velocity and/or any other micro-mechanical sensor (e.g., for measuring movement or for measuring micro-mechanical resonance). For example, inertial sensing device 101 may include one or more gyroscopes in addition to or alternatively to the depicted inertial sensors 106, such that the drift compensation determined is for the drift of the gyroscope(s).

Although various types of inertial sensors 106 and environmental sensors 102, 104, 108 may be used, example design parameters and performance metrics of accelerometer may be as follows: transducer sensitivity: 5.06 μV/g (Voltage/g; here 1 g is acceleration due to Earth's gravity equal to approximately 9.8 m/s²); sensitivity with interface ASIC: 46.0 mV/g; transducer full-scale range: 50 kg; velocity random walk: 335 mm/s/√h; bias instability: 4.5 mg; acceleration random walk: 12 mg/√h; area: 5×5 mm²; and power: 110 mW. Example design parameters and performance metrics of a temperature sensor may be as follows: sensitivity 3 mV/K; resolution: 7 mK @ 1 Hz; area: 155.8×155.8 μm²; and power: 78 μW. Example design parameters and performance metrics of a stress sensor may be as follows: sensitivity 445 V/TPa; resolution: 7 kPa @ 1 Hz; area; 39.7×39.7 μm²; and power: 1.47 mW. These values are for example purposes only and different types of sensors and sensitivities may be used in different embodiments.

Although the non-limiting embodiments shown in FIGS. 1A and 1B and described herein relate to compensating for a drift of an inertial sensor, such arrangements may be used in non-limiting embodiments to compensate for a drift of other micromechanical sensors. For example, the sensing device 101 of FIGS. 1A and 1B may include one or more resonant gravimetric sensors or include one or more resonant timing devices instead of or in addition to inertial sensors 106.

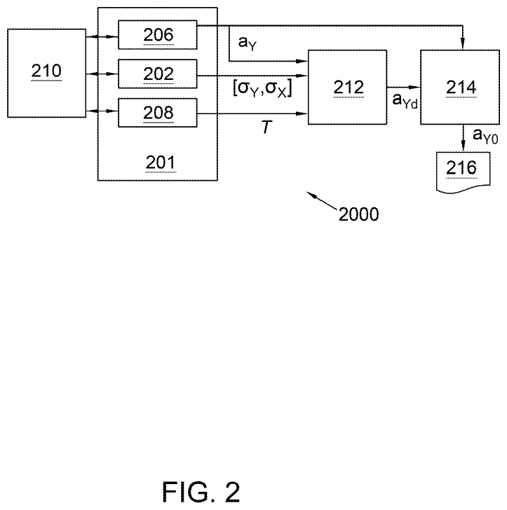

Referring now to FIG. 2, a system 2000 for compensating for drift of an inertial sensor is shown according to non-limiting embodiments or aspects. The system may include an inertial sensing device 201, which may be the same or similar to the inertial sensing device 101 shown in FIG. 1A. The inertial sensing device 201 may include one or more inertial sensors 206, stress sensors 202, and temperature sensors 208, which may be the same or similar to inertial sensors 106 and environmental sensors 102, 104, 108 shown in FIG. 1. The output of the stress sensors 202 may be a function of the difference between Y-stress (σ_{Y}) and X-stress (σ_{X}). The directional sensitivity of the Y-stress sensors is due to the north-south orientation of the release trenches for accelerometer transducers, which isolates the local X-stress. Similarly, the directional sensitivity of the X-stress sensors is due to the release trenches of the accelerometer transducers and the free-end boundary of the chip. In some non-limiting embodiments, the output of the stress sensors may be a function of shear stress or a function of Z-stress (σ_{Z} where Z is out of the plane of the chip).

With continued reference to FIG. 2, the system 2000 includes a computing device 210 used for testing purposes. For example, the computing device 210 may include a testbed module (e.g., testbed computing device), which may include hardware and/or software for programming connections to and generating and supplying reference voltages and currents to the inertial sensors 206 and environmental sensors 202, 204, 208. The computing device 210 may also receive and record sensor signals and/or sensor data from the inertial sensor 206 and sensors 202, 204, 208. The computing device 210 may also generate sensor signals and/or sensor data as simulated outputs for one or more of the inertial sensors 206 and environmental sensors 202, 204, 208. During fabrication and/or initial configuration of the inertial sensor 206, the computing device 210 may be used to characterize the inertial sensor 206 (e.g., model a drift) prior to long-term data collection. For example, appropriate testbed voltages and/or digital settings for optimal device performance may be determined. The bias, acceleration scale factor, and/or Allan deviation may be measured.

In non-limiting embodiments, a testing and data collection process may be carried out using the computing device 210 and/or another device or system. For example, sensor data from the inertial sensor 206 and sensors 202, 204, 208 may be collected over a longer term time period (e.g., 20 to 40 hours) for use in model training, validation, and test set generation. Data collection software executed by the computing device 210 may embed device labels and runtime settings as metadata. Tests may be performed at ambient and/or controlled temperatures and under natural and/or controlled stresses. For example, tests may be conducted in an environmental chamber at various ramp-up and ramp-down applications of temperature. Different mechanical constraints may be placed on the device housing and/or chip supporting the inertial sensing device 201 to generate different relationships between temperature and stress experienced by the inertial sensing device.

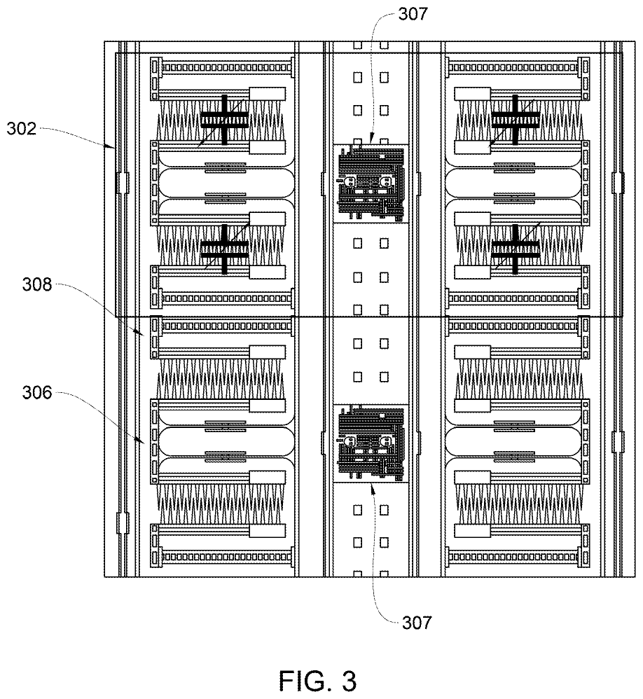

Referring now to FIG. 3, an example arrangement of accelerometers and stress sensors is shown according to a non-limiting embodiment. FIG. 3 illustrates a partial view (four transducer elements) of a larger accelerometer array. In the illustrated example, the accelerometer transducer elements include a 28-ng proof mass and hourglass spring beams, providing a transducer sensitivity that is suitable for high-g, high dynamic range applications, e.g., navigation through high shock. As shown, the full bridge of four sense capacitances formed by a two-element accelerometer array 302 enables a fully differential detection scheme. Y-stress sensors (e.g., y-stress piezo-FETs in the depicted example) 304 are arranged as shown with respect to the accelerometer array and a rotor 306 and stator 308 of the accelerometer transducer elements.

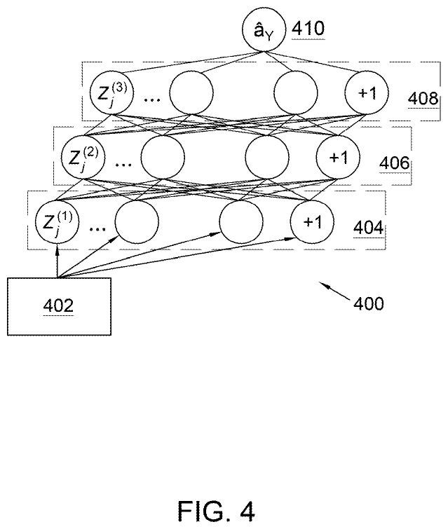

In non-limiting embodiments, and referring back to FIG. 2, the system 2000 includes a neural network estimator module 212 that receives, as input, the outputs of the stress sensors 202, 204, temperature sensors 208, and inertial sensors 206. The neural network estimator module 212 may include, for example, software executed by one or more computing devices. The neural network estimator module 212 may be executed by a computing device arranged external to and/or remote from the inertial sensing device 201. In some non-limiting examples, the neural network estimator module may be part of the inertial sensing device 201 (e.g., as part of an on-chip computing device). The neural network estimator module 212 may be trained with data from the computing device 210. In non-limiting embodiments, the neural network estimator module 212 may be a deep neural network with several fully-connected layers. In some non-limiting embodiments, the neural network estimator module 212 may be a recurrent neural network or a convolutional neural network. FIG. 4 illustrates an example deep neural network architecture 400 having three layers according to non-limiting embodiments or aspects. It will be appreciated that additional layers and other neural-net architectures may be used in other non-limiting embodiments.

With continued reference to FIG. 2, the system 2000 may include a compensation module 214 which may include, for example, software and/or hardware configured to modify an output sensor signal and/or sensor data of the inertial sensor 206 to compensate for the predicted drift determined and output by the neural network estimator module 212. For example, the compensation module 214 may include an on-chip computing device and/or set of program instructions configured to modify the output of the inertial sensor 206 based on a predicted drift that is predetermined and stored within the inertial sensing device 201 or that is determined in real-time or near-real-time during use of the inertial sensing device 201. The compensation module 214 outputs sensor data 216 that has been adjusted based on the predicted drift. In some examples, the compensation module 214 may up-sample the predicted output from the neural network estimator module 212 (e.g., from 0.13 Hz to 50 Hz or the like) and filter the output with a moving average (e.g., a 100 second moving average or the like) to adjust the raw inertial sensor data in a manner that compensates for the predicted drift.

As shown in FIG. 4, a neural network 400 is configured to receive, as input 402, the outputs of the sensors of the inertial sensing device, denoted as (X_{Env}.ϵR¹⁰²) based on the example arrangement shown in FIG. 1A with 102 sensor signals (91 y-stress sensors, 5 x-stress sensors, and 6 temperature sensors). The neural network 400 includes a first fully-connected hidden layer 404 (Zⱼ⁽¹⁾ ϵR¹⁰⁰⁰; where j denotes the unit numbering 1, 2, . . . , 1000). The neural network 400 further includes an intermediate fully-connected hidden layer 406 (Zⱼ⁽²⁾ϵR⁸⁰⁰; j=1, 2, . . . , 800). The neural network 400 also includes a third fully-connected hidden layer 408 (Zⱼ⁽³⁾ ϵR⁵⁰⁰; j=1, 2, . . . , 500). The neural network 400 is configured to generate an output 410 (â_{Y} ϵR¹). The neural network 400 may be implemented with a rectified linear unit activation function, an Adam optimizer with a fixed learning rate of 1×10⁻⁶, and a mean square loss objective function. It will be appreciated that such a configuration is for example purposes only, and that various neural network architectures and techniques may be used to generate an output estimated displacement based on inputted sensor signals.

In non-limiting embodiments, the neural network may be tuned using hyperparameters to improve regression models incorporated by the network. Such hyperparameters may include one or more optimization methods, regularization methods, activation functions, learning rates, and the width and depth of the neural network. The Adam optimizer used in non-limiting embodiments provides a regret bound on the convergence rate that is comparable to results under a convex optimization framework and compares favorably to other stochastic optimization methods. An L2 regularization may be adopted during the training process of the neural network to prevent an over-fitting model. A rectified linear unit activation function and a dynamic learning rate may be used to improve speed and avoid gradient vanishing in the training phase. In addition to studying the drift-compensation results using the three-layer neural network shown in FIG. 4, a grid search for different depths and widths of neural networks with a power of two neurons may be carried out. The length of the neurons varies from 64 to 1024, with an incremental factor of two. The depth of the neural network varies from a single layer to seven layers with an increment of two. Through a grid search for different depths and widths of neural networks in every input data case, the optimal neural network architectures with the lowest training losses may be identified. For example, for a neural network depth of 7 with stress sensors (and without temperature sensors), the layers may have the following number of hidden units (in the order of layers): [129, 256, 512, 1024, 512, 256, 64]. For a neural network depth of 3 that uses stress sensors and temperature sensors, the layers may have the following number of hidden units (in the order of layers): [500, 800, 1000].

In non-limiting embodiments or aspects, the neural network estimator module 212 is configured such that each node generates an instantaneous output of an estimated acceleration random walk (a_{Yo}) (e.g., output 216 in FIG. 2) as a function of the input environmental sensor data (X_{Env}.) based on the following equation where k is the discrete time, W⁽⁴⁾, ϵR⁵⁰¹ is the weights of the output layer, including the bias term, and (⋅) denotes the inner product of two vectors:

$${a}_{Yo} [ k ] = {W}^{( 4 )} [ k ] \cdot [ {Z}^{( 3 )} [ k ] , 1 ] \qquad ( Equation 1 )$$

In Equation 1, [Z⁽ [symbol] ⁾[k], 1] is the augmented vector of Z⁽ [symbol] ⁾[k] with a bias term of 1. Z₍ [symbol] _{)[k] is the vector representation of the hidden units at time k, which can be expressed in terms of hidden units from the last layer according to the following equation where} [symbol] _{is the hidden layer number and g(•) denotes the activation function of the hidden units:}

$${Z}^{( ℓ )} [ k ] = \{ \begin{matrix}g ( {W}^{( ℓ - 1 )} [ k ] [ {Z}^{( ℓ - 1 )} [ k ] , 1 ] ) & ℓ ⩾ 2 \\ g ( {W}^{( ℓ - 1 )} [ k ] [ {x}_{Env} [ k ] , 1 ] ) & ℓ = 1\end{matrix} \qquad ( Equation 2 )$$

The acceleration random walk compensation (e.g., drift compensation) can be determined by subtracting the raw acceleration output a_{Y}[k], from the estimator output, â_{Yd}, as shown in the following equation:

$${a}_{Yo} [ k ] = {a}_{Y} [ k ] - {\hat{a}}_{Yd} [ k ] \qquad ( Equation 3 )$$

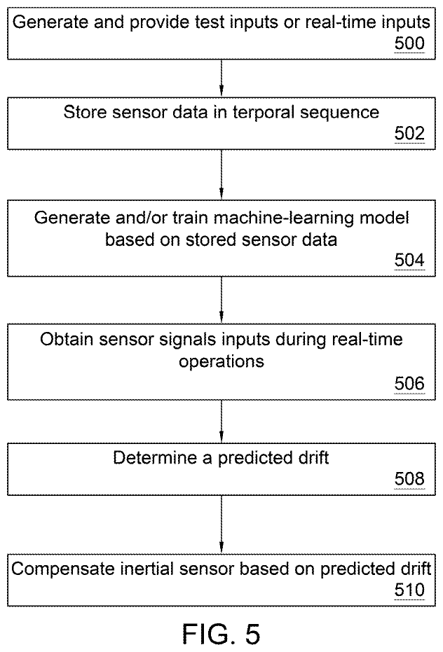

Referring now to FIG. 5, a flow diagram for a method of inertial drift compensation is shown according to non-limiting embodiments. The steps shown in FIG. 5 are for example purposes only, and it will be appreciated that additional, fewer, different, and/or a different order of steps may be used in non-limiting embodiments. At a first step 500, test inputs and/or real-time inputs are generated and provided. For example, a testbed module may be connected to an inertial sensing device so as to provide generated outputs, such as reference voltages and/or currents. In some examples, the inertial sensor may be actively used (e.g., moved). The inertial sensing device, and particularly one or more inertial sensors, such as an accelerometer and/or gyroscope, and one or more environmental sensors, such as stress sensors and temperature sensors, output sensor signals during testing or real-time operation that can be received by a testbed module and/or a computing device.

At step 502, the output sensor signals are stored in sequence and in temporal relation, such that sensor signals from the inertial sensor are associated with sensor signals from the environmental sensors from the same time instance or time period.

At step 504, one or more machine-learning models are generated and/or trained based on the sensor signal data provided at step 500 and stored at step 502. For example, a neural network model may be structured with several layers of nodes (e.g., a deep-learning neural network) that receives, as input, the sensor signal data from a period of time. The sensor signal data may be represented as a vector in some examples. The neural network model may output a predicted drift of one or more inertial sensors.

At step 506, sensor signals are obtained during real-time operation and are input into the machine-learning model generated and/or trained at step 504. At step 508, a predicted drift generated from a predicted bias and predicted scale factor error is determined based on the trained machine-learning model.

At step 510, the inertial sensor can be compensated based on the predicted drift value. For example, an inertial sensor signal output may be modified over time by the inertial sensing device to compensate for the predicted drift.

Following step 504, the trained machine-learning model may be used for various purposes. For example, the trained machine-learning model may be used during real-time operation of an inertial sensing device that is configured with an inertial sensor and environmental sensors to compensate for a predicted drift. In other examples, the trained machine-learning model may be used during manufacturing of an inertial sensing device, such that a manufactured inertial sensing device may be subjected to testing (with a testbed module, simulated use, actual use, and/or the like) to determine a drift compensation that is then used to program the final inertial sensing device for manufacturing and distribution. As an example, the drift compensation determined for an inertial sensing device may be used to program a computing device of the inertial sensing device to modify the inertial sensor signals over time to compensate for the drift.

In non-limiting embodiments, the machine-learning model output may be used to adjust the configuration of the inertial sensor. For example, one or more attributes of the inertial sensor may be modified by physically modifying an accelerometer array. In some non-limiting embodiments, one or more attributes of the inertial sensor may be modified during operation by, for example, affecting the temperature (e.g., with an on-chip heating device or the like) of the inertial sensor.

In non-limiting embodiments, the machine-learning model may be used to create automatic compensation processes that may be programmed into an inertial sensing device during manufacturing. For example, an automatic compensation process may automatically be performed by a computing device of the inertial sensing device at predetermined time intervals to re-configure the inertial sensor. The automatic compensation process may utilize preconfigured compensation values and/or formulae, or in other examples may sample sensor signals and generate compensation values based on real-time usage.

In non-limiting embodiments, the inertial sensing device may be tested in an environment (e.g., an ambient environment) where the inertial sensors and environmental sensors are sampled (e.g., at 50 kHz and 12.6 Hz inter-sensory scan speed, respectively, as an example), using the same or separate data acquisition systems (e.g., using separate 16-bit data acquisition systems as an example). The temperature sensors and stress sensors may be scanned through two independent loops, where a complete cycle for scanning through 96 stress sensors, for example, takes approximately 7.6 seconds. The raw inertial sensor data and temperature sensor data may be down-sampled (e.g., to 0.13 Hz as an example) to align with the stress sensor data.

In non-limiting embodiments, a temporally-aligned data set may be segmented into a training data set, a validation data set, and a testing data set. As an example, a 20-hour inertial sensor and environmental sensor data set may be segmented into a 12-hour training data set, a 4-hour validation data set, and a 4-hour testing data set for the three-layer neural network shown in FIG. 4. The training data set and validation data set may be generated by randomly reshuffling an initial time period worth of data (e.g., an initial 16 hours of data) out of the total time period (e.g., out of 20 hours of data). The last remainder of data (e.g., 4 hours) may be used for testing the performance of the trained neural network and evaluating the performance of the drift compensation. The first portion of data (e.g., an initial 16 hours of data) can be viewed as a calibration phase for the compensation estimator, whereas the subsequent portion of data (e.g., 4-hour test data) may be used to examine the efficacy of the compensation technique in real-time applications where future data is model-agnostic. It will be appreciated that any time periods may be used for training and/or testing purposes, and that the examples described herein are for example purposes only. For example, a non-limiting embodiment using a recurrent neural network model may use a training data set and validation data with sequential time-ordering of the data rather than randomly reshuffling the data.

Non-limiting embodiments described herein may be used for various purposes where accurate inertial measurements are required over a period of time. For example, non-limiting embodiments may be used to manufacture, configure, and/or calibrate inertial sensing devices for use in inertial navigation systems for robotics and/or personal tracking systems. Non-limiting embodiments may also be used in other applications that are affected by external environmental disturbances, including sensors used in precision motion automation, preventative maintenance, and instrument measurement and validation, as examples.

Although embodiments have been described in detail for the purpose of illustration, it is to be understood that such detail is solely for that purpose and that the disclosure is not limited to the disclosed embodiments, but, on the contrary, is intended to cover modifications and equivalent arrangements that are within the spirit and scope of the appended claims. For example, it is to be understood that the present disclosure contemplates that, to the extent possible, one or more features of any embodiment can be combined with one or more features of any other embodiment.

The invention claimed is:

1. A system comprising:
an inertial sensing device comprising:
an inertial sensor; and
a plurality of stress sensors configured to measure stress applied to the inertial sensing device; and
at least one computing device configured to:
receive sensor data from the inertial sensor and the plurality of stress sensors; and
determine a drift compensation of the inertial sensor based on the sensor data.

2. The system of claim 1, wherein the inertial sensing device comprises the at least one computing device.

3. The system of claim 1, wherein the at least one computing device comprises at least one first processor arranged in the sensing device and at least one second processor external to the sensing device.

4. The system of claim 1, wherein the inertial sensing device further comprises a plurality of environmental sensors in addition to the plurality of stress sensors, and wherein the drift compensation is determined at least partially based on sensor data received from the plurality of environmental sensors.

5. The system of claim 4, wherein the plurality of environmental sensors comprises at least one of the following: a temperature sensor, a resonator oscillator sensor, a strain sensor, a gas chemical sensor, or any combination thereof.

6. The system of claim 1, wherein the sensor data is received while the inertial sensing device is moved.

7. The system of claim 6, wherein the at least one computing device is further configured to record the sensor data to temporally associate measurements from the inertial sensor with stress measurements from the plurality of stress sensors.

8. The system of claim 1, wherein determining the drift compensation is based on a machine-learning algorithm.

9. The system of claim 8, where the machine-learning algorithm comprises a deep neural network.

10. The system of claim 9, wherein the deep neural network comprises a first fully-connected hidden layer, a second fully-connected hidden layer, and a third fully-connected hidden layer.

11. The system of claim 8, wherein the machine-learning algorithm outputs a predicted drift value, and wherein the drift compensation is based on the predicted drift value.

12. The system of claim 1, wherein the inertial sensor comprises an array of accelerometers.

13. The system of claim 1, wherein the inertial sensor comprises at least one gyroscope or an array of gyroscopes.

14. The system of claim 1, wherein the inertial sensing device comprises a chip, and wherein the inertial sensor and the plurality of stress sensors are arranged on the chip.

15. The system of claim 14, further comprising a data storage device comprising an association between each stress sensor of the plurality of stress sensors and at least one of the following: an accelerometer of the array of accelerometers, a position on the chip supporting the array of accelerometers, a position on the chip relative to an accelerometer of the array of accelerometers, or any combination thereof.

16. The system of claim 1, further comprising:
a testbed computing device in communication with the inertial sensing device, the testbed computing device configured to generate signals configured to produce the sensor data from the inertial sensor and the plurality of stress sensors.

17. A method comprising:
capturing a plurality of inertial sensor signals comprising inertial sensor data from at least one inertial sensor arranged in an inertial sensing device while the inertial sensing device is moved;
capturing a plurality of environmental sensor signals comprising environmental sensor data from a plurality of stress sensors arranged in the inertial sensing device while the inertial sensing device is moved;
temporally associating the inertial sensor data with the environmental sensor data; and
determining, with at least one processor, a drift compensation for the at least one inertial sensor based on the inertial sensor data and the environmental sensor data.

18. The method of claim 17, further comprising:
adjusting a configuration of the at least one inertial sensor based on the drift compensation.

19. The method of claim 18, wherein adjusting the configuration of the at least one inertial sensor comprises at least one of the following: modifying an attribute of the at least one inertial sensor, modifying an algorithm that processes the inertial sensor data, or any combination thereof.

20. The method of claim 17, wherein determining the drift compensation comprises:
inputting the environmental sensor data into a machine-learning model configured to output a predicted drift value, wherein the drift compensation is based on the predicted drift value.

21. The method of claim 20, wherein the machine-learning model comprises a deep neural network comprising a first fully-connected hidden layer, a second fully-connected hidden layer, and a third fully-connected hidden layer.

22. The method of claim 20, further comprising:
training the machine-learning model based on training input data generated with a testbed computing device.

23. An inertial sensing device comprising:
an inertial sensor; and
a plurality of stress sensors arranged on the inertial sensing device and configured to measure stress applied to the inertial sensing device.

24. The inertial sensing device of claim 23, further comprising an interface configured to output sensor data from the inertial sensor and the plurality of stress sensors.

25. The inertial sensing device of claim 23, further comprising a plurality of temperature sensors.

26. The inertial sensing device of claim 23, further comprising at least one computing device configured to determine a drift compensation of the inertial sensor based on sensor data from the inertial sensor and the plurality of stress sensors.

27. The inertial sensing device of claim 26, wherein the drift compensation is determined based on a machine-learning model.

28. The inertial sensing device of claim 27, wherein the machine-learning model comprises a deep neural network.

29. The inertial sensing device of claim 28, wherein the deep neural network comprises a first fully-connected hidden layer, a second fully-connected hidden layer, and a third fully-connected hidden layer.

30. The inertial sensing device of claim 27, wherein the machine-learning model outputs a predicted drift value, and wherein the drift compensation is based on the predicted drift value.

31. The inertial sensing device of claim 23, wherein the inertial sensor comprises an array of accelerometers.

32. The inertial sensing device of claim 23, wherein the inertial sensor comprises at least one gyroscope or any array of gyroscopes.

33. The inertial sensing device of claim 23, further comprising a chip, the chip including the inertial sensor and the plurality of stress sensors.

34. A system comprising:
a sensing device comprising:
at least one micromechanical sensor; and
a plurality of environmental sensors configured to measure at least one environmental parameter of the sensing device; and
at least one computing device configured to:
receive sensor data from the at least one micromechanical sensor and the plurality of environmental sensors; and
determine a drift compensation of the micromechanical sensor based on the sensor data.

35. The system of claim 34, wherein the plurality of environmental sensors comprises at least one of the following types of sensors: a stress sensor, a temperature sensor, a resonance oscillator sensor, a strain sensor, a gas chemical sensor, or any combination thereof.

36. The system of claim 34, wherein the at least one micromechanical sensor comprises at least one of the following: an inertial sensor, a resonant gravimetric sensor, a resonant timing device, or any combination thereof.

37. The system of claim 1, wherein the inertial sensor comprises an array of gyroscopes.

38. The system of claim 1, wherein the inertial sensor comprises a plurality of accelerometers and a plurality of gyroscopes.

39. The system of claim 34, wherein the plurality of environmental sensors comprises a plurality of magnetometers.
